(19) United States
(12) Patent Application Publication
(10) Pub. No.: US 2002/0135050 A1
(43) Pub. Date: Sep. 26, 2002

(54) Semiconductor device

(75) Inventor: Naoto Kimura, Kumamoto (JP)

Correspondence Address: YOUNG & THOMPSON, 745 SOUTH 23RD STREET 2ND FLOOR, ARLINGTON, VA, 22202

(73) Assignee: NEC CORPORATION, Tokyo (JP)

(21) Appl. No.: 10/096,839

(22) Filed: Mar. 14, 2002

(30) Foreign Application Priority Data
Mar. 23, 2001 (JP) 85789/2001

(51) Int. Cl. H01L 23/495

(52) U.S. Cl. 257/668

(57) ABSTRACT

A semiconductor device comprises a mounting board, a package electrically connected to the mounting board through connection balls attached to the mounting board, a semiconductor chip carried on the package, and bonding wires for electrically connecting connection terminals provided on the semiconductor chip to the connection balls, the semiconductor chip and the connection balls are attached to one surface of a tape, the tape has such a shape that is bent by 180° to make a surface of the tape having the semiconductor chip attached thereon in substantially parallel to a surface of the tape having the connection balls attached thereon with a buffering material intervening therebetween, and the bonding wires and the connection balls are electrically connected to each other with connection wiring formed in the tape.

### BACKGROUND OF THE INVENTION

1. Field of the Invention

The present invention relates to a semiconductor device, and more particularly, it relates to a surface-mounted package structure.

2. Description of the Related Art

The mode of mounting a semiconductor device includes a lead wire insertion type and a surface mounting type, and the surface mounting type is becoming the mainstream for attaining high density surface mounting.

Among various modes of surface mounting type, FIG. 4 is a cross sectional view showing a mounted state where a BGA (ball grid array) package having plural ball grids on a lower surface is mounted on a mounting board.

As shown in FIG. 4, a semiconductor chip 114 carried on a BGA package 110 is electrically connected to ball grids 112 through wires 115 and leads 113. Wiring terminals 102 are provided on a surface of a printed circuit board 101. The ball grids 112 are superposed on the wiring terminals 102 and then melted by heating, whereby the ball grids 112 are fixed on the wiring terminals 102.

However, when the printed circuit board 101 is warped due to an external force, such a problem occurs that the ball grids 112 of the BGA package 110 are released from the wiring terminals 102.

This is caused by the fact that the rigidity of the BGA package 110 is higher than the rigidity of the printed circuit board 101, and therefore, the deformation of the BGA package 110 cannot follow the deformation of the printed circuit board 101.

### SUMMARY OF THE INVENTION

An object of the invention is to provide a semiconductor device that can reduce the release of a package from a printed circuit board.

The invention relates to a semiconductor device comprising a mounting board, a package electrically connected to the mounting board through connection balls attached to the mounting board, a semiconductor chip carried on the package, and bonding wires for electrically connecting connection terminals provided on the semiconductor chip to the connection balls, the semiconductor chip and the connection balls being attached to one surface of a tape, the tape having such a shape that is bent by 180° to make a surface of the tape having the semiconductor chip attached thereon in substantially parallel to a surface of the tape having the connection balls attached thereon with a buffering material intervening therebetween, and the bonding wires and the connection balls being electrically connected to each other with connection wiring formed in the tape.

### BRIEF DESCRIPTION OF THE DRAWINGS

The above-mentioned and other objects, features and advantages of the invention will become more apparent by reference to the following detailed description of the invention taken in conjunction with the accompanying drawings, wherein:

FIG. 1A and FIG. 1B are cross sectional views showing a first embodiment of the semiconductor device of the invention according to the order of the production process steps thereof;

FIG. 2 is a cross sectional view showing a second embodiment of the semiconductor device of the invention;

FIG. 3 is a cross sectional view showing a modified embodiment of the second embodiment of the semiconductor device of the invention; and

FIG. 4 is a cross sectional view showing a conventional semiconductor device.

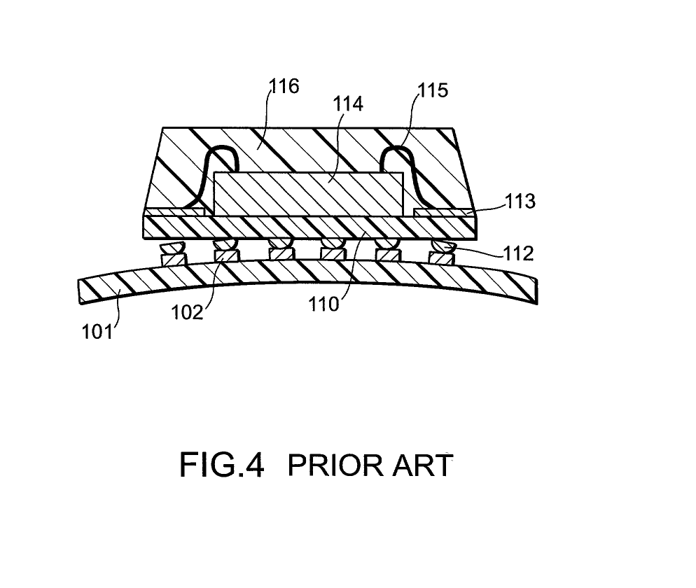

### DETAILED DESCRIPTION OF THE INVENTION

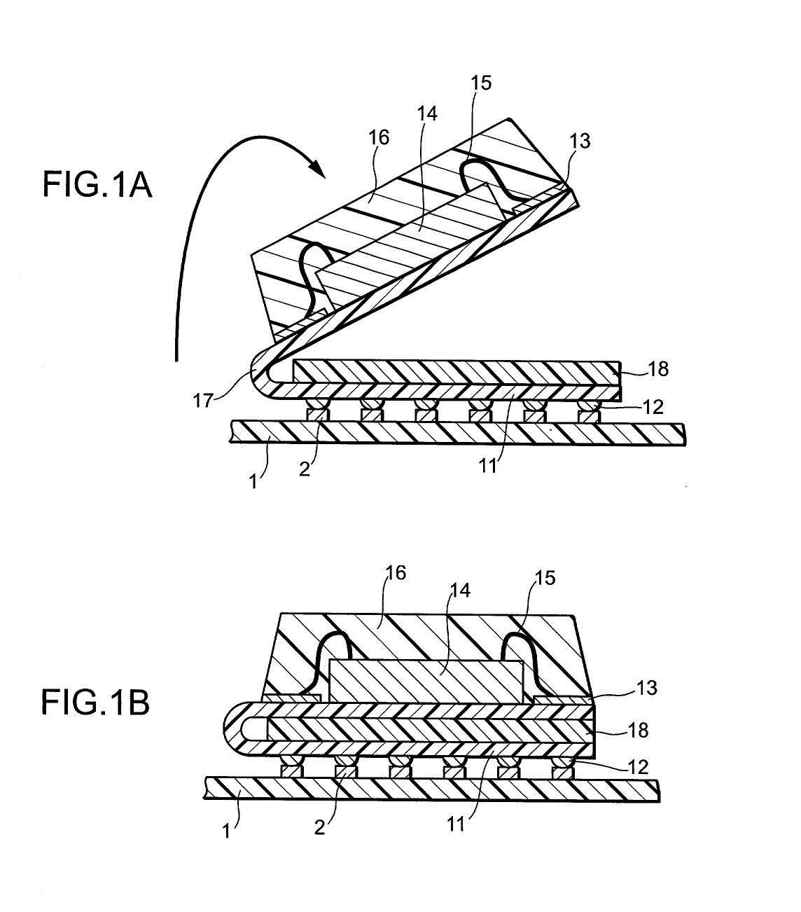

A first embodiment of the semiconductor device of the invention will be described with reference to FIGS. 1A and 1B. FIGS. 1A and 1B are cross sectional views showing a semiconductor package and a printed circuit board on a cut plane passing solder balls and wiring terminals. FIGS. 1A and 1B also show process steps of a production process of the first embodiment.

A printed circuit board 1 having wiring terminals 2 provided thereon, solder balls 12 and a board wiring 13 formed on a flexible tape 11, a semiconductor chip 14 attached on the tape 11, wires 15 for connecting the semiconductor chip 14 and the board wiring 13, and an epoxy resin 16 for sealing the semiconductor chip 14 and the wires 15 are provided. At this time, the solder balls 12, the board wiring 13, the wires 15 and the epoxy resin 16 are all provided on the same surface of the tape 11. The tape 11 is divided into a region of the semiconductor chip 14 and a region of the solder balls 12, and also a bending region 17 having no member formed thereon is provided for bending the region of the semiconductor chip 14 of the tape 11 into the direction shown by the arrow in the figure.

After attaching the solder balls 12 formed on the flexible tape 11 to the wiring terminals 2 provided on the printed circuit board 1, the tape 11 is bent in the direction shown by the arrow with the bending region 17 as the bending axis, so as to obtain the cross section shown in the figures.

Before starting the bending operation of the tape 11, a silicone resin 18 as a buffering material is attached to the surface of the tape 11 opposite to the surface having the solder balls 12 provided thereon (FIG. 1A).

When the tape 11 is further bent in the direction shown by the arrow, the surface of the tape 11 opposite to the surface having the semiconductor chip 14 provided thereon is attached to the silicone resin 18. (FIG. 1B).

The region of the tape carrying the semiconductor chip 14 and the region of the tape having the solder balls 12 attached thereon are attached to each other through the silicone resin 18 but are not directly attached, whereby distortion applied to the semiconductor chip side due to the bending deformation of the printed circuit board 1 can be relaxed, and failures, such as breakage of the wire and release of the chip, can be suppressed.

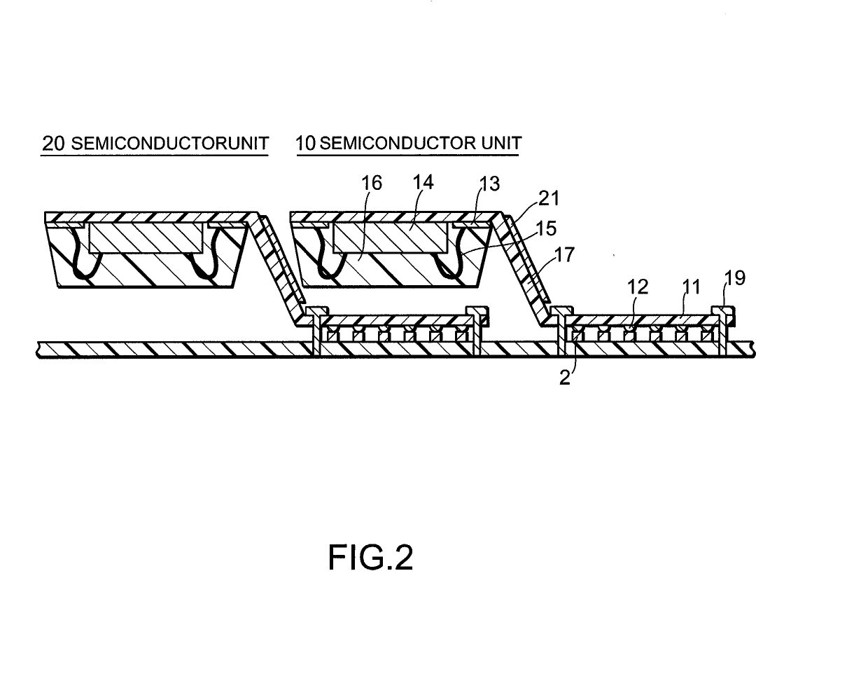

A second embodiment of the semiconductor device of the invention will be described with reference to FIG. 2. FIG. 2 is across sectional view showing the second embodiment of the semiconductor device of the invention.

As similar to the first embodiment, the solder balls 12, the board wiring 13, the wires 15 and the epoxy resin 16 are all formed on the same surface of the flexible tape 11, and the tape 11 is divided into a region of the semiconductor chip 14 and a region of the solder balls 12 by a bending region 17.

After attaching the solder balls 12 formed on the flexible tape 11 to the wiring terminals 2 provided on the printed circuit board 1, the tape 11 is bent in such a manner that the region of the tape 11 of the semiconductor chip 14 and the region of the tape 11 of the solder balls 12 are not aligned on the same plane while maintaining the linearity of the bending region 17. Specifically, the tape of the bending region 17 is attached to a resin or a metal (for example, copper) for reinforcement as a reinforcing material 21 as shown in the figure, and thus is formed to have a linear form.

At this time, in order to attach the solder balls 12 and the wiring terminals 2 in a secure manner, the periphery of theregionofthetapellhavingthesolderballs12attached thereto is fixed to the printed circuit board 1 with screws 19 penetrating the tape 11 to reach the printed circuit board 1.

The tape 11 is thus divided into the semiconductor chip region and the solder ball region with the bending region 17 bent in a linear form intervening therebetween, and all the members constitute one semiconductor unit 10.

Another semiconductor unit 20 having the same constitution as the semiconductor unit 10 is formed adjacent to the semiconductor unit 10. The semiconductor unit 20 shown in the figure is arranged on the printed circuit board 1 in such a manner that the solder ball region of the tape of the semiconductor unit 20 is positioned beneath the semiconductor unit 10.

Therefore, the area on the printed circuit board occupied by the semiconductor unit can be limited to the region of the tape having the solder balls attached thereto, and thus it is advantageous to high density mounting of semiconductor units on the printed circuit board.

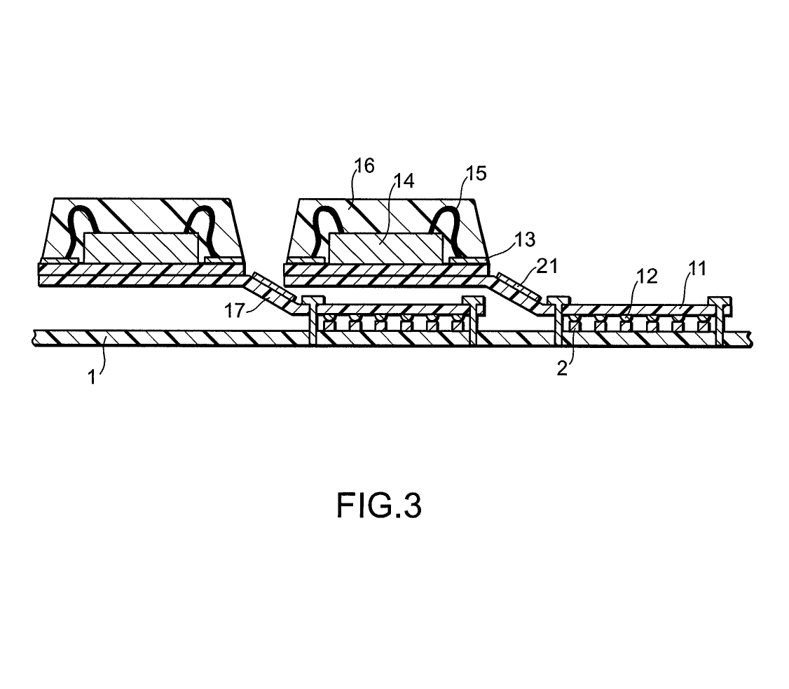

As a modified embodiment of the second embodiment, it is possible as shown in FIG. 3 that the board wiring 13, the wires 15 and the epoxy resin 16 are formed on the surface of the flexible tape 11 opposite to the surface thereof having the solder balls 12 are formed thereon.

As described in the foregoing, in such an embodiment that the semiconductor chip and the solder balls are attached to the different regions on the flexible tape, and the semiconductor chip region and the solder ball region of the tape are superposed on each other in the same plane, the adverse affect of distortion of the printed circuit board to the semiconductor chip region of the tape is relaxed by the silicone resin as a buffering material intervening between the semiconductor region and the solder ball region of the tape.

In another embodiment that the semiconductor region and the solder ball region of the tape are not superposed on each other on the same plane, when plural semiconductor units formed on one tape are mounted on the printed circuit board, the solder ball region of the tape of one semiconductor unit is superposed on the semiconductor region of the tape of the adjacent semiconductor unit in the same plane, whereby the semiconductor units can be integrated on the printed circuit board at a high density.

In the embodiment of the semiconductor device according to the invention, as having been described, in which the semiconductor chip and the solder balls are attached to different regions of the flexible tape, and the semiconductor region of the tape and the solder ball region of the tape are superposed on each other in the same plane, the adverse affect of distortion of the printed circuit board to the semiconductor chip region of the tape is relaxed by the silicone resin as a buffering material intervening between the semiconductor region and the solder ball region of the tape.

In another embodiment that the semiconductor region and the solder ball region of the tape are not superposed on each other on the same plane, when plural semiconductor units formed on one tape are mounted on the printed circuit board, the solder ball region of the tape of one semiconductor unit is superposed on the semiconductor region of the tape of the adjacent semiconductor unit in the same plane, whereby the semiconductor units can be integrated on the printed circuit board at a high density.

Although the invention has been described with reference to specific embodiments, the description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor device comprising a mounting board, a package electrically connected to the mounting board through connection balls attached to the mounting board, a semiconductor chip carried on the package, and bonding wires for electrically connecting connection terminals provided on the semiconductor chip to the connection balls, the semiconductor chip and the connection balls being attached to one surface of a tape, the tape having such a shape that is bent by 180° to make a surface of the tape having the semiconductor chip attached thereon in substantially parallel to a surface of the tape having the connection balls attached thereon with a buffering material intervening therebetween, and the bonding wires and the connection balls being electrically connected to each other with connection wiring formed in the tape.

2. A semiconductor device as claimed in claim 1, wherein the buffering material is a silicone resin.

3. A semiconductor device comprising a mounting board, a package electrically connected to the mounting board through connection balls attached to the mounting board, a semiconductor chip carried on the package, and bonding wires for electrically connecting connection terminals provided on the semiconductor chip to the connection balls, the tape being bent in such a manner that a region of the tape having the package and a region of the tape having the connection balls facing each other between distance with respect to a surface of the mounting board and being in substantially parallel to each other, and the bonding wires and the connection balls being electrically connected to each other with connection wiring formed in the tape.

4. A semiconductor device as claimed in claim 3, wherein the semiconductor chip and the connection balls are attached on the same surface of the tape.

5. A semiconductor device as claimed in claim 3, wherein the semiconductor chip and the connection balls are attached on different surfaces of the tape.

6. A semiconductor device as claimed in claim 3, wherein plural semiconductor units each comprising the package, the connection balls and the tape are mounted on the mounting board, and the package of one of the semiconductor units is positioned above the connection balls of another of the semiconductor units adjacent thereto.

7. A semiconductor device as claimed in claim 3, wherein a region of the tape between the region of the tape having the package and the region of the tape having the connection balls is attached to a resin or a metal for reinforcement to make the region therebetween having a linear form.
